(19) United States
(12) Patent Application Publication
(10) Pub. No.: US 2012/0087083 A1
(43) Pub. Date: Apr. 12, 2012

(54) MOUNTING APPARATUS FOR STORAGE DEVICE

(75) Inventors: CHIN-WEN YEH, Tu-Cheng (TW); ZHI-JIAN PENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/110,088

(22) Filed: May 18, 2011

(30) Foreign Application Priority Data
Oct. 12, 2010 (CN) 201010504462.9

(51) Int. Cl. H05K 7/14

(52) U.S. Cl. 361/679.33

(57) ABSTRACT

A mounting apparatus includes a drive bracket, and a restricting member. The drive bracket is secured to a front plate of an electronic enclosure, and includes a bottom plate and a side plate connected to the bottom plate. A path, substantially parallel to the bottom plate, is defined in the side plate. A connecting portion, substantially perpendicular to the bottom plate, is located in the path. The restricting member includes a resisting portion connected to the connecting portion and received in the path. A first end of the resisting portion is located on an outer surface of the side plate, a second opposite end of the resisting portion extends into an inner surface of the side plate, and the second opposite end of the resisting portion abuts a storage device.

### BACKGROUND

1. Technical Field

The present disclosure relates to a mounting apparatus for mounting a storage device.

2. Description of Related Art

In a conventional computer, a storage device is typically secured to a drive bracket with screws. A significant drawback to this is that the insertion and removal of screws is cumbersome and time consuming. In addition, a tool such as a screwdriver is usually required. Moreover, the screws can be accidentally lost during assembly or disassembly.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, cutaway view of a mounting apparatus and a storage device in accordance with an embodiment.

FIG. 2 is an assembled view of FIG. 1.

FIG. 3 is similar to FIG. 2, but viewed from a different aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

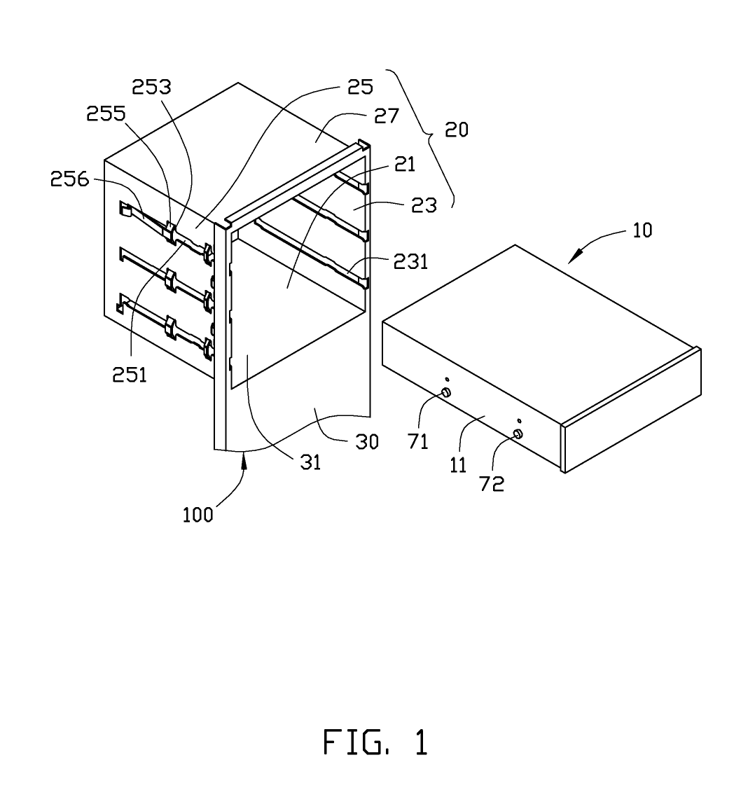

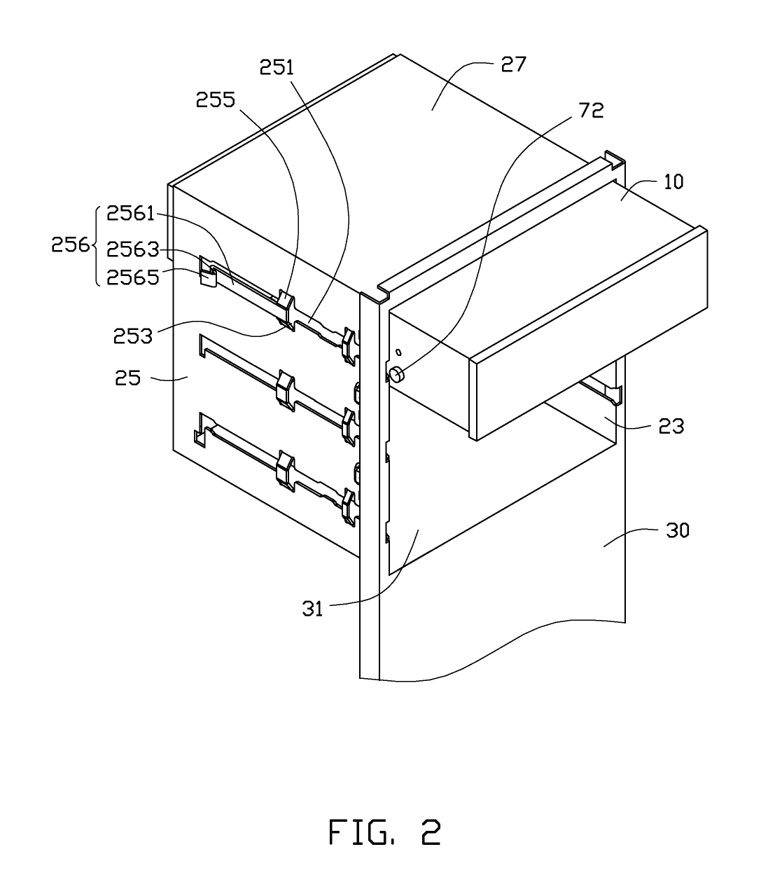

Referring to FIGS. 1-2, a mounting apparatus in accordance with an embodiment includes an enclosure 100. The enclosure 100 can enclose a plurality of electronic elements, such as a motherboard, a power supply, expansion cards, and so on. The enclosure 100 includes a front plate 30 and a drive bracket 20 attached to the front plate 30. A plurality of storage devices 10 (only one is shown in FIG. 1) is received in the drive bracket 20. In one embodiment, the storage devices 10 can be hard disks or optical disk drives.

A through opening 31 is defined in the front plate 30, for the storage device 10 to be inserted in the drive bracket 20. The storage device 10 includes two substantially identical side panels 11. For the sake of simplification, explanation of only one side panel 11 is provided. A first positioning post 71 and a second positioning post 73 protrude from the side panel 11.

The drive bracket 20 includes a bottom plate 21, a first side plate 25, a second side plate 23, and a top plate 27. In one embodiment, the bottom plate 21 is substantially parallel to the top plate 27, and the first side plate 25 is substantially parallel to the second side plate 23 and perpendicular to the bottom plate 21.

A plurality of first paths 251 (only three shown in FIGS. 1-3) is defined in the first side plate 25, and a plurality of second paths 231 (only three shown in FIGS. 1-3) is defined in the second side plate 23. In one embodiment, an extending direction of the first paths 251 is the same as that of the plurality of second paths 231 and substantially parallel to the bottom plate 21. Each first path 251 has the same configuration as each second path 231, for the sake of simplification, explanation of only the first paths 251 is provided. A cutout 253, with a connecting portion 255, is defined in the center of the one of the first path 251. In one embodiment, the connecting portion 255 is a bridge, for a space defined between the connecting portion 255 and the first side plate 25.

A restricting member 256 is connected to the connecting portion 255 and includes a resisting portion 2561, an operating portion 2565, and a clipping portion 2563 located between the resisting portion 2561 and the operating portion 2565. The resisting portion 2561 extends to an end of the first path 251 from a top portion of the connecting portion 255. In one embodiment, a first end of the resisting portion 2561 is located at an outer surface of the first side plate 25, and an opposite second end of the resisting portion 2561 extends into an inner surface of the first side plate 25. The clipping portion 2563 and the operating portion 2565 cooperatively define a V-shape. The clipping portion 2563 is at an acute angle to the operating portion 2565, and the clipping portion 2563 is also at an acute angle to the resisting portion 2561.

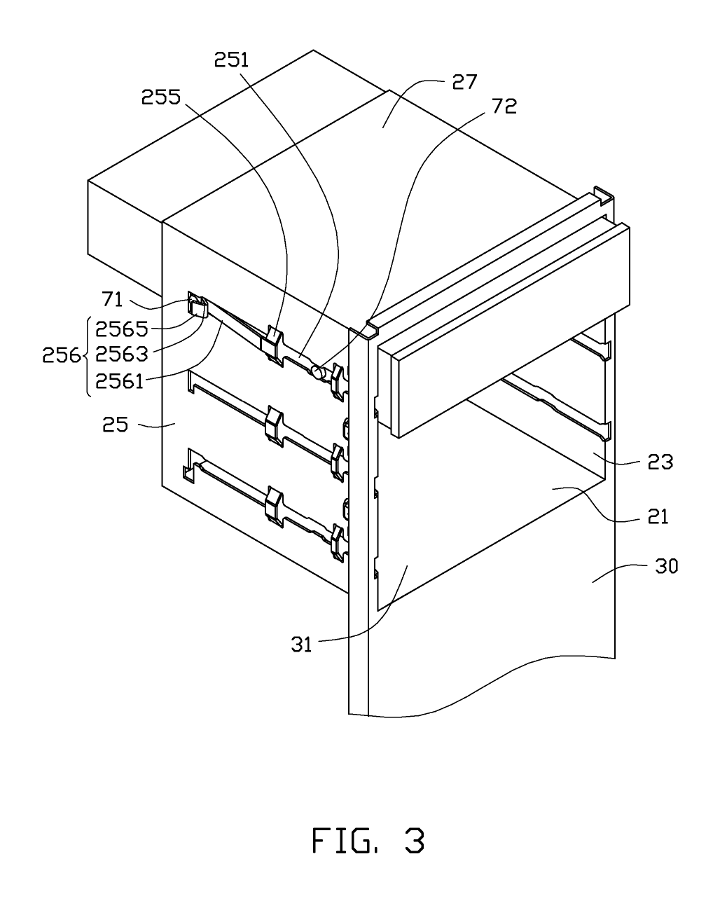

Referring to FIGS. 2-3, in assembly, the storage device 10 is put into the drive bracket 20 via the through opening 31 of the front plate 30, and the side panel 11 abuts an inner surface of the first side plate 25. The first and second positioning posts 71, 72 are received in the corresponding one of the plurality of first paths 251. The storage device 10 is pushed in a first direction towards the drive bracket 20, until the first positioning post 71 is stopped by the resisting portion 2561. The storage device 10 is further pushed in the first direction, to deform the restricting member 256 in a second direction away from the storage device 10. When the first positioning post 71 has passed through the resisting portion 2561, the restricting member 256 is released in a direction opposite to the second direction. Therefore, the first positioning post 71 is clipped between the clipping portion 2563 and the operating portion 2565. In one embodiment, the second direction is substantially perpendicular to the first direction.

In disassembly, the operating portion 2565 is operated in the second direction, and the first positioning post 71 is disengaged from the clipping portion 2563. The storage device 10 is pulled in a direction opposite to the first direction and out of the drive bracket 20.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
a drive bracket comprising a bottom plate and a side plate connected to the bottom plate; a path, substantially parallel to the bottom plate, defined in the side plate, and a connecting portion, substantially perpendicular to the bottom plate, located in the path; and
a restricting member comprising a resisting portion, the resisting portion connected to the connecting portion and received in the path;
wherein a first end of the resisting portion is located on an outer surface of the side plate, a second opposite end of the resisting portion extends into an inner surface of the side plate, and the second opposite end of the resisting portion is adapted for abutting a storage device.

2. The mounting apparatus of claim 1, wherein the resisting portion is substantially perpendicular to the connecting portion.

3. The mounting apparatus of claim 1, wherein the restricting member further comprises a clipping portion connected to the resisting portion, and the clipping portion is adapted to engage a positioning post of the storage device.

4. The mounting apparatus of claim 3, wherein the clipping portion is at an acute angle to the resisting portion.

5. The mounting apparatus of claim 3, wherein the restricting member further comprises an operation portion, and the operation portion is adapted to deform the restricting member.

6. The mounting apparatus of claim 5, wherein the operation portion is at an acute angle to the clipping portion.

7. The mounting apparatus of claim 5, wherein a space, adapted for receiving the positioning post, is defined between the resisting portion and the operating portion.

8. The mounting apparatus of claim 1, wherein a cutout, that extends substantially perpendicular to the bottom plate, is defined in the side plate, the cutout is in communication with the path, and the connecting portion is connected to opposite edges of the cutout.

9. A mounting apparatus comprising:
an enclosure comprising a front plate;
a drive bracket secured to the front plate, the drive bracket comprising a side plate, a path defined in the side plate, and a connecting portion located in the path; and
a restricting member, received in the path, comprising a resisting portion, an operating portion, and a clipping portion located between the resisting portion and the operating portion; a first end of the resisting portion is connected to the connecting portion and located on an outer surface of the side plate; and an opposite second end of the resisting portion extending into an inner surface of the side plate;
wherein the resisting portion is adapted to elastically abut the storage device, and a space is defined between the resisting portion and the operating portion.

10. The mounting apparatus of claim 9, wherein the clipping portion and the operating portion define a V-shape.

11. The mounting apparatus of claim 9, wherein the drive bracket further comprises a bottom plate connected to the side plate, and the path is substantially parallel to the bottom plate.

12. The mounting apparatus of claim 9, wherein the resisting portion is substantially perpendicular to the connecting portion.

13. The mounting apparatus of claim 9, wherein the clipping portion is at an acute angle to the resisting portion.

14. The mounting apparatus claim 9, wherein the operation portion is at an acute angle to the clipping portion.

15. The mounting apparatus claim 9, wherein a cutout is defined in the side plate, the cutout is in communication with the path, and the connecting portion is connected to opposite edges of the cutout.

16. The mounting apparatus of claim 15, wherein the connecting portion is a bridge.

17. A mounting apparatus comprising:
a drive bracket comprising a side plate, a path defined in the side plate, and a connecting portion located in the path;
a storage device comprising a positioning post; and
a restricting member, received in the path, comprising a resisting portion, an operating portion, and a clipping portion located between the resisting portion and the operating portion; a first end of the resisting portion is connected to the connecting portion and located on an outer surface of the side plate; and an opposite second end of the resisting portion extending into an inner surface of the side plate;
wherein the resisting portion is elastic, and the positioning post is located between the resisting portion and the operation portion.

18. The mounting apparatus of claim 17, wherein the clipping portion and the operating portion define a V-shape.

19. The mounting apparatus of claim 17, wherein the drive bracket further comprises a bottom plate connected to the side plate, and the path is substantially parallel to the bottom plate.

20. The mounting apparatus of claim 17, wherein the resisting portion is substantially perpendicular to the connecting portion.
